(19) United States
(12) Patent Application Publication
(10) Pub. No.: US 2019/0296181 A1
(43) Pub. Date: Sep. 26, 2019

(54) ALUMINUM GALLIUM ARSENIDE AND INDIUM GALLIUM PHOSPHIDE POWER CONVERTER ON SILICON

(71) Applicant: INTERNATIONAL BUSINESS MACHINES CORPORATION, Armonk, NY (US)

(72) Inventors: Ning Li, White Plains, NY (US); Kevin Han, Berkeley, CA (US); William T. Spratt, Croton-on-Hudson, NY (US); Stephen W. Bedell, Wappingers Falls, NY (US); Devendra Sadana, Pleasantville, NY (US); Ghavam G. Shahidi, Pound Ridge, NY (US)

(21) Appl. No.: 15/935,635

(22) Filed: Mar. 26, 2018

(51) Int. Cl. H01L 31/18; H01L 31/077; H01L 31/0304; H01L 31/0352; H01L 31/0224; H01L 31/0216

(52) U.S. Cl. CPC H01L 31/1844; H01L 31/077; H01L 31/03042; H01L 31/02161; H01L 31/035281; H01L 31/022408; H01L 31/03046

(57) ABSTRACT

A semiconductor structure for optical power conversion and a method of forming the semiconductor structure are provided. In an aspect, the method may include removing a first portion of the semiconductor structure from a first region, wherein the semiconductor structure comprises a layered photovoltaic structure on a silicon-on-insulator structure. A second portion of the semiconductor structure may be removed from a second region, wherein the second region is located adjacent to the first region, and wherein an insulator layer of the silicon-on-insulator structure is exposed by the removed second portion. A passivation layer pattern may be formed over the semiconductor structure. Electrodes may be formed on portions of the surfaces of the semiconductor structure that are uncovered by the passivation layer.

### BACKGROUND

The present invention relates generally to the fields of optoelectronics and photovoltaics, and in particular to semiconductor fabrication processes and associated structures for optical power conversion.

A transducer may convert one form of energy into another form of energy, for example, optical energy into electrical energy. An optical input signal may be received by the transducer in the form of electromagnetic radiation, or light, and an electrical output signal may be generated by the transducer in the form of electrical power. The input signal may include a narrowband optical energy signal such as in the form of a laser beam composed of a narrow band of wavelengths. The output signal may be collected from the transducer in the form of a voltage potential and electrical current. The laser beam may be propagated from a source to the transducer, such as through a vacuum, or a medium such as a solid, liquid, or gas. A solid medium may include, for example, a waveguide such as an optical fiber. The transducer may be applied, for example, in various far field wireless power transmission techniques. For example, the transducer may be implemented in a photovoltaic device and positioned at a receiving end of a laser beam. The laser beam may be propagated from a source and received by the photovoltaic device to enable remote power delivery to the device. In another example, the transducer may be implemented in a photocommunications device and positioned at a receiving end of a laser beam to enable optical communications by and with the device.

### SUMMARY

A semiconductor structure for optical power conversion and a method of forming the semiconductor structure are provided. In an aspect, the method may include removing a first portion of the semiconductor structure from a first region, wherein the semiconductor structure comprises a layered photovoltaic structure on a silicon-on-insulator structure. A second portion of the semiconductor structure may be removed from a second region, wherein the second region is located adjacent to the first region, and wherein an insulator layer of the silicon-on-insulator structure is exposed by the removed second portion. A passivation layer pattern may be formed over the semiconductor structure. Electrodes may be formed on portions of the surfaces of the semiconductor structure that are uncovered by the passivation layer.

### BRIEF DESCRIPTION OF THE DRAWINGS

The following detailed description, given by way of example and not intended to limit the invention solely thereto, will best be appreciated in conjunction with the accompanying Figures. The Figures are not necessarily to scale. The Figures are merely schematic representations, not intended to portray specific parameters of the invention. The Figures are intended to depict only typical embodiments of the invention. In the Figures, like numbering represents like elements.

FIG. 1 depicts a cross-sectional view of a semiconductor structure, in accordance with an embodiment of the present invention.

FIG. 2 depicts a cross-sectional view of a semiconductor structure following patterning and etching, in accordance with an embodiment of the present invention.

FIG. 3 depicts a cross-sectional view of a semiconductor structure following patterning and etching, in accordance with an embodiment of the present invention.

FIG. 4 depicts a cross-sectional view of a semiconductor structure following deposition of a passivation layer, in accordance with an embodiment of the present invention.

FIG. 5 depicts a cross-sectional view of a semiconductor structure following patterning and etching, in accordance with an embodiment of the present invention.

FIG. 6 depicts a cross-sectional view of a semiconductor structure following evaporation and deposition, in accordance with an embodiment of the present invention.

FIG. 7 depicts a cross-sectional view of a wafer following evaporation and deposition, in accordance with an embodiment of the present invention.

FIG. 8 depicts a comparison of open-circuit voltage and current generated by various semiconductor structures, in accordance with an embodiment of the present invention.

### DETAILED DESCRIPTION

Detailed embodiments of the present invention are disclosed herein for purposes of describing and illustrating claimed structures and methods that may be embodied in various forms, and are not intended to be exhaustive in any way, or limited to the disclosed embodiments. Many modifications and variations will be apparent to those of ordinary skill in the art without departing from the scope and spirit of the disclosed embodiments. The terminology used herein was chosen to best explain the principles of the one or more embodiments, the practical application or technical improvement over technologies found in the marketplace, or to enable others of ordinary skill in the art to understand the embodiments disclosed herein. As described, details of well-known features and techniques may be omitted to avoid unnecessarily obscuring the embodiments of the present invention.

References in the specification to “one embodiment”, “an embodiment”, “an example embodiment”, or the like, indicate that the embodiment described may include one or more particular features, structures, or characteristics, but it shall be understood that such particular features, structures, or characteristics may or may not be common to each and every disclosed embodiment of the present invention herein. Moreover, such phrases do not necessarily refer to any one particular embodiment per se. As such, when one or more particular features, structures, or characteristics is described in connection with an embodiment, it is submitted that it is within the knowledge of those skilled in the art to effect such one or more features, structures, or characteristics in connection with other embodiments, where applicable, whether or not explicitly described.

For purposes of the description hereinafter, the terms “upper,” “lower,” “right,” “left,” “vertical,” “horizontal,” “top,” “bottom,” “perpendicular,” “parallel,” and the like, and any derivatives thereof, shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary layers at the interface of the two elements.

In the interest of not obscuring disclosure of embodiments of the present invention, the following detailed description may contain certain processing steps or operations that are known in the art which may have been combined for purposes of clear description and illustration. In some instances, certain processing steps or operations that are known in the art may not be described in detail and/or may not be described at all. It shall be understood that the following disclosure of embodiments of the present invention is relatively focused on distinctive elements, features, structures, or characteristics thereof.

A far field wireless power transmission technique for laser power conversion requiring efficient power conversion of a narrowband optical input signal to an electrical output signal may implement a compound semiconductor device such as a transducer. The device may include semiconducting materials that may be chosen to provide certain electrical properties to the device for enabling a particular response by the device in response to an applied optical input signal. The device performance may be characterized, for example, in terms of power conversion efficiency. The power conversion efficiency may be defined as the ratio of the optical power input to the device to the electrical power output from the device. The device performance may be optimized with respect to a narrowband optical energy signal such as in the form of a laser beam to maximize the power conversion efficiency. For purposes of the present disclosure, a band of frequencies or wavelengths of an optical input signal may be referred to in terms of a mean frequency or wavelength of the band.

Embodiments of the present invention are directed to a compound semiconductor device and a corresponding method of manufacture. In an aspect, the device may include a photovoltaic semiconductor structure including AlGaAs and InGaP semiconductor materials that may be grown on a silicon on insulator substrate. The device may be implemented in optical power conversion. Advantageously, growing the materials on the silicon substrate in accordance with the present disclosure reduces defects, increases power conversion efficiency, and enables higher voltage potential generation compared to photovoltaic semiconductor structures including GaAs semiconductor materials that may be grown on the substrates.

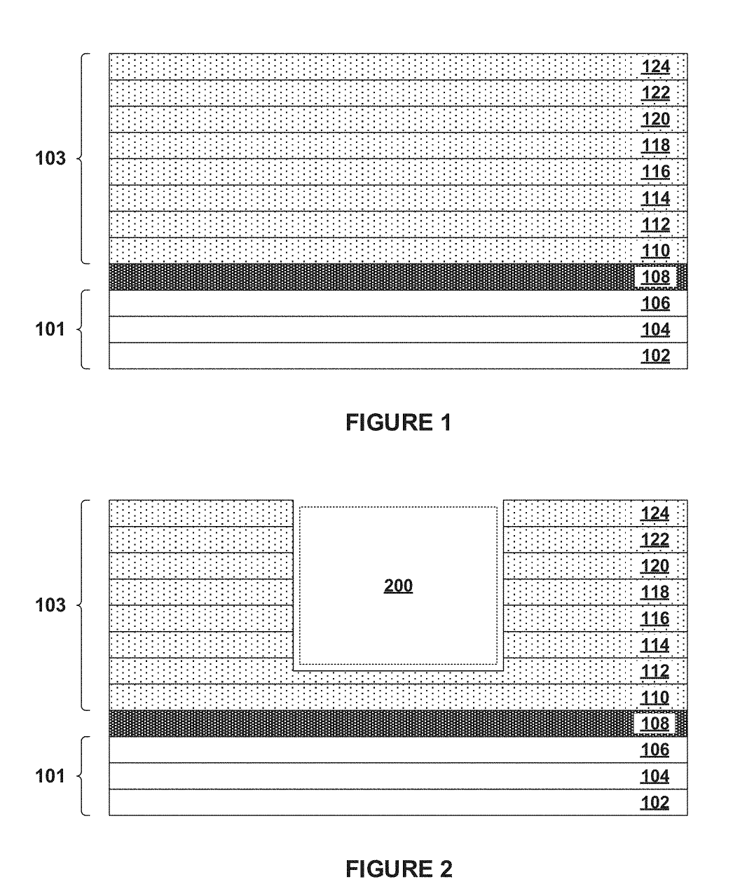

With reference to FIG. 1, a semiconductor structure including wafer 101 may include a buffer layer 108 and epitaxial layers 103. Wafer 101 represents, for example, a semiconductor substrate. In an example embodiment of the present invention, wafer 101 may be a silicon-on-insulator (SOI) substrate, which may include a buried insulator layer 104 below a cap layer 106, and a base semiconductor layer 102 below the buried insulator layer 104. In the example embodiment, the cap layer 106 may be one of a silicon layer and an offcut silicon layer. The buried insulator layer 104 may isolate the cap layer 106 from the base semiconductor layer 102. The base semiconductor layer 102 may be made from any of several known semiconductor materials such as, for example, silicon, germanium, silicon-germanium alloy, carbon-doped silicon, carbon-doped silicon-germanium alloy, and compound (e.g. III-V and II-VI) semiconductor materials. Non-limiting examples of compound semiconductor materials include gallium arsenide, indium arsenide, and indium phosphide. Typically the base semiconductor layer 102 may be approximately, but is not limited to, several hundred microns thick. For example, the base semiconductor layer 102 may have a thickness ranging from approximately 0.5 mm to approximately 1.5 mm. Other thicknesses for the base semiconductor layer 102, the buried insulator layer 104, and the cap layer 106 that are below and/or above the aforementioned thickness ranges may also be employed in the present disclosure.

In the example embodiment, the buffer layer 108 may be of germanium (Ge) and may be formed on wafer 101 to a thickness within a range of 1 to 10 μm. In the example embodiment, a first bottom contact layer 110 of indium gallium phosphide (InGaP) may be formed on the buffer layer 108 to a thickness within a range of 1 to 100 nm, preferably 10 to 50 nm. In the example embodiment, a second bottom contact layer 112 of zinc gallium-arsenide may be formed on the first bottom contact layer 110 to a thickness within a range of 1000 to 5000 nm, preferably 2000 to 4000 nm. In the example embodiment, a back surface and absorption layer 114 of zinc aluminum-gallium-arsenide (AlₓGa₁₋ₓAs) may be formed on the second bottom contact layer 112 to a thickness within a range of 50 to 150 nm, preferably 85 to 115 nm. In the example embodiment, a first absorption layer 116 of zinc aluminum-gallium-arsenide (AlₓGa₁₋ₓAs) may be formed on the back surface and absorption layer 114 to a thickness within a range of 1 to 5 μm, preferably 2.5 to 3.5 μm. In the example embodiment, a second absorption layer 118 of not intentionally doped (NID) aluminum-gallium-arsenide (AlₓGa₁₋ₓAs) may be formed on the first absorption layer 116 to a thickness within a range of 1 to 25 nm, preferably 8 to 12 nm. In the example embodiment, a third absorption layer 120 of silicon aluminum-gallium-arsenide (AlₓGa₁₋ₓAs) may be formed on the second absorption layer 118 to a thickness within a range of 50 to 150 nm, preferably 85 to 115 nm. In the example embodiment, a window and absorption layer 122 of silicon aluminum-gallium-arsenide (AlₓGa₁₋ₓAs) may be formed on the third absorption layer 120 to a thickness greater than approximately 200 nm, preferably within a range of 800 to 1200 nm. In the example embodiment, a top contact layer 124 of silicon gallium-arsenide may be formed on the window and absorption layer 122 to a thickness within a range of 1 to 100 nm, preferably 10 to 40 nm. The aforementioned layers may otherwise be formed to thicknesses below and/or above the aforementioned thickness ranges that may be chosen as a matter of design.

In an alternative embodiment of the present invention, the first absorption layer 116, the second absorption layer 118, and the third absorption layer 120 may otherwise be of zinc indium-gallium-phosphide, not intentionally doped (NID) indium gallium phosphide, and silicon indium-gallium-phosphide, respectively.

In the example embodiment, the back surface and absorption layer 114 of zinc aluminum-gallium-arsenide may include an alloy composition of approximately 60% Al and 40% Ga (i.e., AlₓGa₁₋ₓAs, where x=0.6). In the example embodiment, the first absorption layer 116 of zinc aluminum-gallium-arsenide may include an alloy composition of approximately 35% Al and 65% Ga (i.e., AlₓGa₁₋ₓAs, where x=0.35). In the example embodiment, the second absorption layer 118 of not intentionally doped (NID) aluminum-gallium-arsenide may include an alloy composition of approximately 35% Al and 65% Ga (i.e., AlₓGa₁₋ₓAs, where x=0.35). In the example embodiment, the third absorption layer 120 of silicon aluminum-gallium-arsenide may include an alloy composition of approximately 35% Al and 65% Ga (i.e., Al_{0.35}Ga_{0.65}As, where x=0.35). In the example embodiment, the window and absorption layer 122 of silicon aluminum-gallium-arsenide may include an alloy composition of approximately 60% Al and 40% Ga (i.e., Al_{0.6}Ga_{0.4}As, where x=0.6).

In the example embodiment, the second bottom contact layer 112 may include a dopant concentration of approximately 3×10¹⁸ atoms cm⁻³. In the example embodiment, the back surface and absorption layer 114 may include a dopant concentration of approximately 1×10^{18 atoms cm}⁻³. In the exemplary embodiment, the first absorption layer 116 may include a dopant concentration of approximately 1×10¹⁷ atoms cm⁻³. In the example embodiment, the third absorption layer 120 may include a dopant concentration of approximately 1×10¹⁸ atoms cm⁻³. In the exemplary embodiment, the window and absorption layer 122 may include a dopant concentration of approximately 3×10¹⁸ atoms cm³. In the example embodiment, the top contact layer 124 may include a dopant concentration of approximately 5×10¹⁸ atoms cm⁻³.

The terms “epitaxial growth and/or deposition” and “epitaxially formed and/or grown” mean the growth of a semiconductor material on a deposition surface of a semiconductor material, in which the semiconductor material being grown may have the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth and/or deposition processes may be selective to forming on semiconductor surfaces, and may not deposit material on dielectric surfaces, such as silicon dioxide or silicon nitride surfaces.

The formation, via deposition or growth, of various semiconductor layers as described in the present disclosure may be achieved by any suitable deposition process or technique such as metal organic chemical vapor deposition (MOCVD), chemical beam epitaxy (CBE), molecular beam epitaxy (MBE), solid phase epitaxy (SPE), hydride vapour phase epitaxy, or a combination thereof. Various layer characteristics may be affected by varying corresponding growth parameters and conditions to optimize device performance or manufacturability. The growth parameters and conditions may include, for example, growth temperature, growth pressure, growth pressure ratio (e.g., III-V ratio in growing III-V semiconductor layers), alloy composition, residual strain, growth rate, doping levels, surfactant gases applied, applied annealing cycles, etc.

With reference to FIG. 2, material may be removed from a first region 200 of the semiconductor structure by lithographic patterning and etching. In the example embodiment, the first region 200 may be located above wafer 101. In the example embodiment, the material may be removed by etching through the top contact layer 124, the window and absorption layer 122, the third absorption layer 120, the second absorption layer 118, the first absorption layer 116, the back surface and absorption layer 114, and a portion of the second bottom contact layer 112. The material may be removed, for example, by applying a photolithographic patterning process which may include forming a photoresist or resist pattern (not depicted) on the top contact layer 124. The resist pattern may be used as an etching mask during the subsequently applied etching process. The etching process may include, for example, any type of wet or dry etching process such as wet chemical etching, reactive ion etching, or plasma etching. In the example embodiment, the etching process may be applied from the top contact layer 124 to the second bottom contact layer 112, as depicted in FIG. 2. The etching process may be timed or otherwise performed to stop at the second bottom contact layer 112. The resist pattern may subsequently be removed. In the example embodiment, the etching process may be a wet etching process. In the embodiment, the wet etching process may implement a wet etchant including phosphoric acid (H₃PO₄), hydrogen peroxide (H₂O₂), and water (H₂O) at a volume ratio of 1 to 1 to 10.

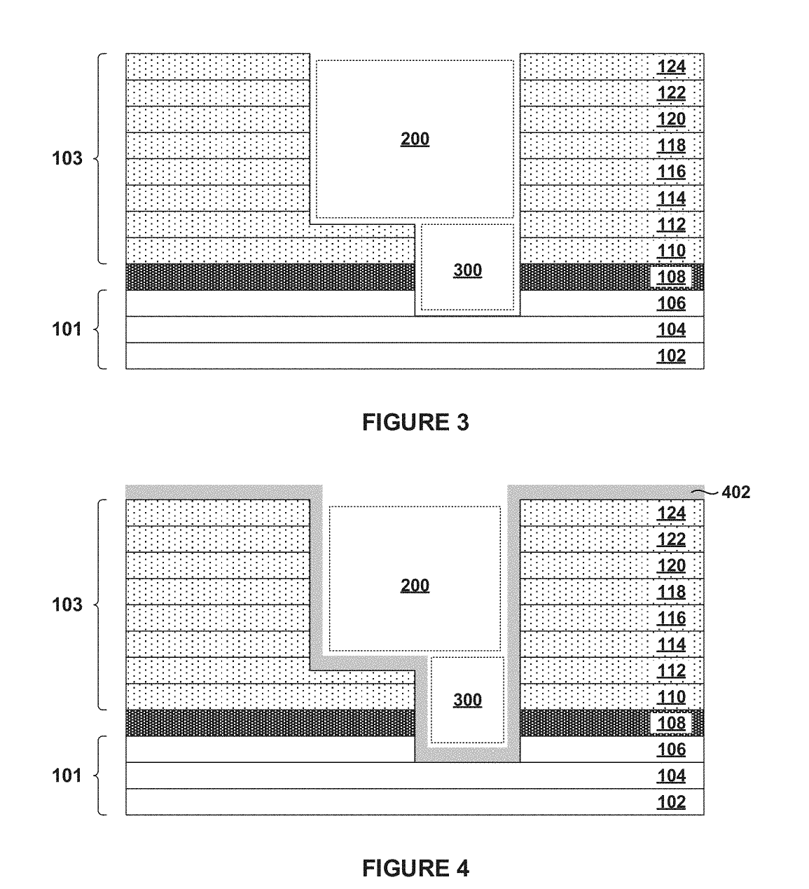

With reference to FIG. 3, material may be removed from a second region 300 of the semiconductor structure by lithographic patterning and etching, such as described with reference to FIG. 2. In the example embodiment, the second region 300 may be located above wafer 101 and below the first region 200. In the example embodiment, the material may be removed by etching through the second bottom contact layer 112, the first bottom contact layer 110, the buffer layer 108, and the cap layer 106. In the example embodiment, the removal of the material may be stopped at the buried insulator layer 104. In the example embodiment, the second region 300 may extend between the first region 200 and the buried insulator layer 104. In the example embodiment, the etching process may be applied from the second bottom contact layer 112 to the buried insulator layer 104, as depicted in FIG. 3. The etching process may be timed or otherwise performed to stop at the buried insulator layer 104. In the example embodiment, the etching process may be a wet etching process. In the example embodiment, the wet etching process applied to the first bottom contact layer 110 may implement a wet etchant including hydrochloric acid (HCl) and phosphoric acid (H₃PO₄) at a volume ratio of 1 to 1. In the example embodiment, the wet etching process applied to the buffer layer 108 may implement a wet etchant including hydrogen peroxide (H₂O₂) at a temperature of 50° C. In the example embodiment, the wet etching process applied to the cap layer 106 may implement a wet etchant including tetramethylammonium hydroxide (TMAH).

With reference to FIG. 4, passivation film 402 may be formed on the semiconductor structure by deposition on wafer 101, the buffer layer 108, and epitaxial layers 103. In the example embodiment, passivation film 402 may be formed for surface passivation of exposed surfaces of wafer 101, the buffer layer 108, and epitaxial layers 103, as depicted in FIG. 4. The surface passivation may be applied to insulate or otherwise protect the surfaces during subsequent fabrication steps in accordance with embodiments of the present invention. In the example embodiment, passivation film 402 may be formed by atomic layer deposition (ALD). In the example embodiment, passivation film 402 may be formed to a thickness within a range of 1 to 50 nm, preferably 10 to 30 nm. In the example embodiment, passivation film 402 may be composed of various oxides or nitrides such as aluminum oxide (e.g., Al₂O₃), silicon oxide, or silicon nitride (e.g., Si₃N₄). Passivation film 402 may be formed by any suitable deposition process or technique such as chemical vapor deposition (CVD), physical vapor deposition (PVD), molecular beam deposition (MBD), pulsed laser deposition (PLD), or liquid source misted chemical deposition (LSMCD).

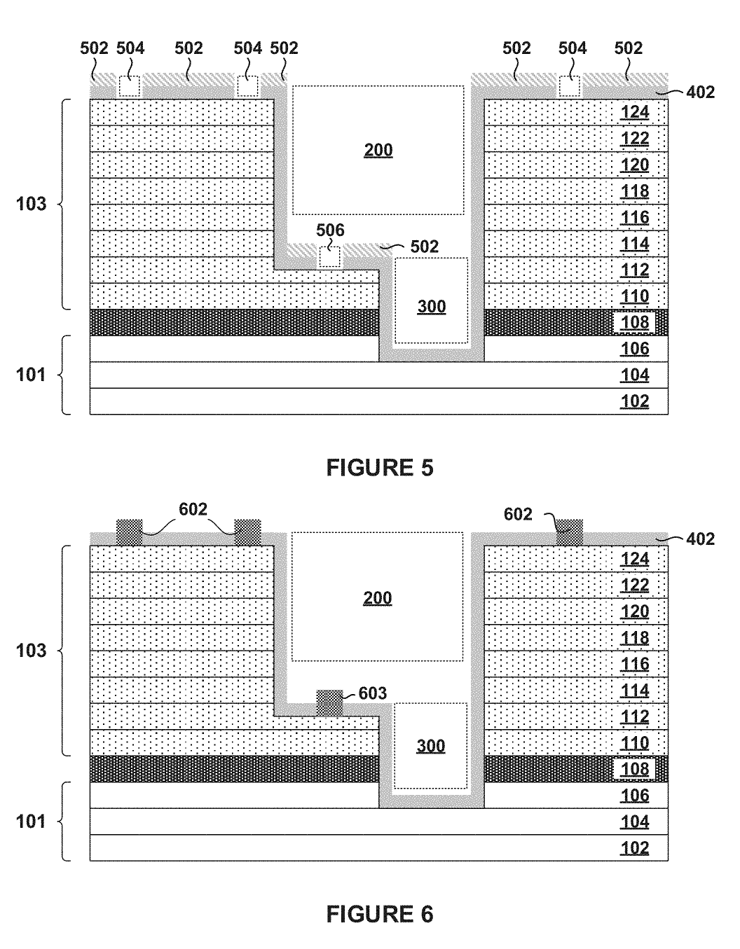

With reference to FIG. 5, resist pattern 502 may be formed over passivation film 402 by lithographic patterning for subsequent etching, such as described with reference to FIG. 2. In the example embodiment, following the patterning, passivation film 402 may be etched by a buffered oxide etchant (BOE) with respect to resist pattern 502. In the example embodiment, passivation film 402 may be etched to form recessed regions 504 to expose portions of surfaces of the top contact layer 124 and the second bottom contact layer 112, as depicted in FIG. 5. The buffered oxide etchant may include, for example, a solution composed of a mixture of a buffering agent and hydrofluoric acid (HF). In the example embodiment, the buffered oxide etchant may include, for example, a 1 to 9 volume ratio of the buffering agent to the hydrofluoric acid. As an example, the buffered oxide etchant may include a 1 to 9 volume ratio of 40% ammonium fluoride (NH₄F) in water to 49% hydrofluoric acid in water.

With reference to FIG. 6, electrodes having contacts 602 and 603 may be formed on the semiconductor structure by evaporation and deposition. The evaporation and deposition may be applied by a thin-film deposition process such as described with reference to FIG. 4. In the example embodiment, contacts 602 may be formed in the recessed regions 504 on the exposed surfaces of the top contact layer 124, as depicted in FIG. 6. In the embodiment, contact 603 may be formed in recess 506 on the exposed surfaces of the second bottom contact layer 112, as depicted in FIG. 6. In the embodiment, contacts 602 and 603 may be formed, for example, by sequential deposition of titanium (Ti), palladium (Pd), and gold (Au), in said sequence, at thicknesses of approximately 20 nm, 30 nm, and 50 nm, respectively. In the example embodiment, resist pattern 502 may subsequently be removed by lift-off.

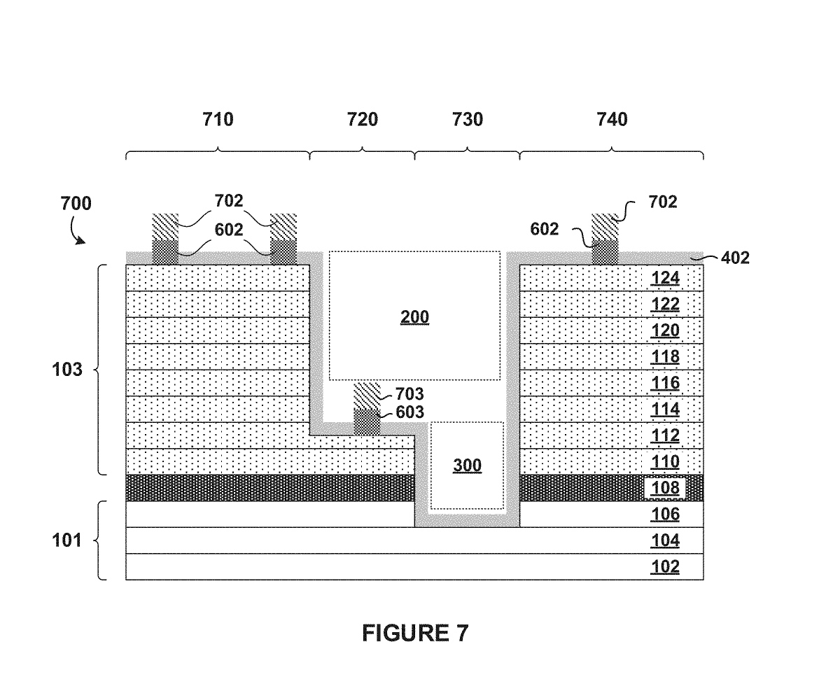

With reference to FIG. 7, electrodes having interconnects 702 and 703 may be formed on the semiconductor structure by evaporation and deposition. The evaporation and deposition may be applied by a thin-film deposition process such as described with reference to FIG. 4. In the example embodiment, interconnects 702 and 703 may be formed on contacts 602 and 603, as depicted in FIG. 7. In the example embodiment, interconnects 702 and 703 may be formed, for example, by sequential deposition of titanium, copper (Cu), and titanium, in said sequence, at thicknesses within ranges of 25 to 35 nm, 150 to 250 nm, and 25 to 35 nm, respectively. In the example embodiment, interconnects 702 and 703 may include, for example, a seed layer, and may be electroplated with copper to a thickness within a range of 2 to 3 μm, preferably 1.25 to 1.75 μm. Excess material such as the seed layer, resist patterns, masks, and the like, may subsequently be removed by etching such as described with reference to FIG. 2, and/or a planarization process such as chemical-mechanical planarization (CMP). The aforementioned deposition thicknesses may otherwise include thicknesses below and/or above the aforementioned thickness ranges that may be chosen as a matter of design.

Following formation of the electrodes, compound semiconductor device 700 may be fabricated, as depicted in FIG. 7. In an embodiment of the present invention, compound semiconductor device 700 may include a layered semiconducting structure having a base formed by wafer 101. Wafer 101 may include a buried insulator layer 104 below a cap layer 106, and a base semiconductor layer 102 below the buried insulator layer 104. In the example embodiment, a buffer layer 108 may include a bottom surface located on and above wafer 101, particularly on and above the cap layer 106. In the example embodiment, a first bottom contact layer 110 may include a bottom surface located on and above the buffer layer 108. In the example embodiment, a second bottom contact layer 112 may include a bottom surface located on and above the first bottom contact layer 110. In the example embodiment, a back surface and absorption layer 114 may include a bottom surface located on and above the second bottom contact layer 112. In the example embodiment, a first absorption layer 116 may include a bottom surface located on and above the back surface and absorption layer 114. In the example embodiment, a second absorption layer 118 may include a bottom surface located on and above the first absorption layer 116. In the example embodiment, a third absorption layer 120 may include a bottom surface located on and above the second absorption layer 118. In the example embodiment, a window and absorption layer 122 may include a bottom surface located on and above the third absorption layer 120. In the example embodiment, a top contact layer 124 may include a bottom surface located on and above the window and absorption layer 122.

In the embodiment, compound semiconductor device 700 may include a first section 710 defined by the top contact layer 124, the window and absorption layer 122, the third absorption layer 120, the second absorption layer 118, the first absorption layer 116, the back surface and absorption layer 114, the second bottom contact layer 112, the first bottom contact layer 110, the buffer layer 108, the cap layer 106, the buried insulator layer 104, and the base semiconductor layer 102. In the embodiment, compound semiconductor device 700 may further include a second section 720 defined by the second bottom contact layer 112, the first bottom contact layer 110, the buffer layer 108, the cap layer 106, the buried insulator layer 104, and the base semiconductor layer 102. The second section 720 may be located adjacent to the first section 710 and below the first region 200, as depicted in FIG. 7. In the embodiment, compound semiconductor device 700 may further include a third section 730 defined by the buried insulator layer 104 and the base semiconductor layer 102. The third section 730 may be located adjacent to the second section 720 and below the second region 300, as depicted in FIG. 7. In the embodiment, compound semiconductor device 700 may further include a fourth section 740 defined by the same layers as described with reference to the first section 710 of the first structure. The fourth section 740 may be located adjacent to the third section 730, as depicted in FIG. 7.

In the embodiment, the third section 730 may be an isolating structure or section, for isolating the fourth section 740 from the first and second sections 710 and 720.

In the embodiment, a passivation film 402 may cover the vertical side surfaces of the top contact layer 124, the window and absorption layer 122, the third absorption layer 120, the second absorption layer 118, the first absorption layer 116, the back surface and absorption layer 114, the second bottom contact layer 112, the first bottom contact layer 110, the buffer layer 108, and the cap layer 106, as depicted in FIG. 7. In the embodiment, the passivation film 402 may also cover portions of the horizontal surfaces of the top contact layer 124, the second bottom contact layer 112, and the cap layer 106, as depicted in FIG. 5.

In the embodiment, compound semiconductor device 700 may include one or more electrodes located on and above the uncovered portions of the horizontal surfaces of the top contact layer 124 and the second bottom contact layer 112. In various embodiments, compound semiconductor device 700 may include one or more electrodes located on and above the uncovered portions of the cap layer 106 (not depicted). Each of the electrodes may extend above a top surface of the surrounding passivation film 402, as depicted in FIG. 7.

As an example, one or more of the electrodes located on and above the uncovered portions of the top contact layer 124 may be electrically connected to one or more of the electrodes located on and above the uncovered portions of the second bottom contact layer 112. The electrodes may be electrically connected through the intervening layers between the top contact layer 124 and the second bottom contact layer 112. Advantageously, the composition of the layers, as described in the present disclosure, enables higher open-circuit voltage generation by compound semiconductor device 700, compared to other compound semiconductor devices having other III-V materials that may be grown directly on a silicon substrate.

In the embodiment, a transducer such as a photovoltaic cell, a photodiode, and the like, may be created and implemented on compound semiconductor device 700. In the embodiment, a voltage potential may be generated between an electrode located on and above an uncovered portion of the top contact layer 124, and an electrode located on and above an uncovered portion of the second bottom contact layer 112. For example, the voltage potential may be generated between a first electrode formed by a contact 602 and interconnect 702, and a second electrode formed by a contact 603 and interconnect 703. The voltage potential may be generated, for example, upon application of an optical input signal (i.e., photons) to a top surface of compound semiconductor device 700. The electrodes of compound semiconductor device 700 may be, for example, connected to a power storage device such as a battery for storage of generated electrical power. The power may be extracted, for example, from a positive electrode formed by the first electrode and a negative electrode formed by the second electrode.

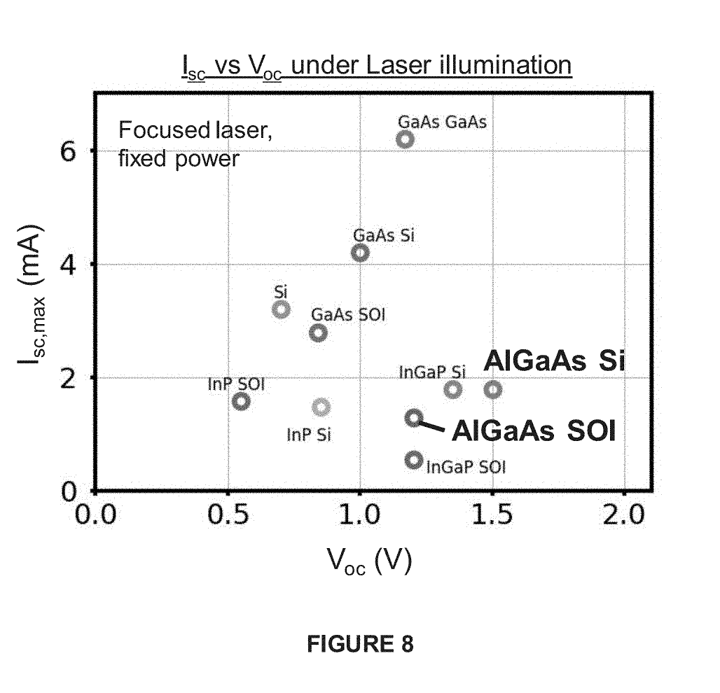

With reference to FIG. 8, a comparison of open-circuit voltage and current generated by various semiconductor structures is depicted. As shown, the photovoltaic semiconductor structure in accordance with embodiments of the present invention, which includes AlGaAs and/or InGaP semiconductor materials that are grown on a silicon-on-insulator substrate, generates more power for a given optical input compared to that generated by the various semiconductor structures.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

What is claimed is:

1. A method of forming a semiconductor structure, the method comprising:
removing a first portion of the semiconductor structure from a first region, wherein the semiconductor structure comprises a layered photovoltaic structure on a silicon-on-insulator structure;
removing a second portion of the semiconductor structure from a second region, wherein the second region is located adjacent to the first region, and wherein an insulator layer of the silicon-on-insulator structure is exposed by the removed second portion;
forming a passivation layer pattern over the semiconductor structure; and
forming electrodes on portions of the surfaces of the semiconductor structure that are uncovered by the passivation layer.

2. The method of claim 1, wherein the pattern of the passivation layer is formed by a buffered oxide etchant.

3. The method of claim 1, wherein the electrodes are formed on the uncovered surfaces of a top contact layer and a bottom contact layer of the semiconductor structure.

4. The method of claim 1, wherein the silicon-on-insulator structure comprises a base substrate layer, a buried insulator layer located above the base silicon substrate layer, and a cap layer located above the buried silicon dioxide insulator layer.

5. The method of claim 4, wherein the cap layer comprises a silicon layer.

6. The method of claim 4, wherein the cap layer comprises an offcut silicon layer.

7. The method of claim 1, wherein the semiconductor structure comprises a germanium buffer layer located between the layered photovoltaic structure and the silicon-on-insulator structure.

8. The method of claim 1, wherein the layered photovoltaic structure comprises a bottom contact layer located above the silicon-on-insulator structure, a back surface and absorption layer located above the bottom contact layer, an absorption layer located above the back surface and absorption layer, a window and absorption layer located above the absorption layer, and a top contact layer located above the window and absorption layer.

9. The method of claim 8, wherein the bottom contact layer is comprised of indium-gallium-phosphide.

10. The method of claim 8, wherein the bottom contact layer is comprised of zinc gallium-arsenide.

11. The method of claim 8, wherein the back surface and absorption layer is comprised of zinc aluminum-gallium-arsenide.

12. The method of claim 8, wherein the absorption layer is comprised of zinc aluminum-gallium-arsenide.

13. The method of claim 8, wherein the absorption layer is comprised of a not intentionally doped (NID) aluminum-gallium-arsenide.

14. The method of claim 8, wherein the absorption layer is comprised of silicon aluminum-gallium-arsenide.

15. The method of claim 8, wherein the window and absorption layer is comprised of silicon aluminum-gallium-arsenide.

16. The method of claim 8, wherein the top contact layer is comprised of silicon gallium-arsenide.

17. A semiconductor structure comprising:
a silicon-on-insulator structure;
a first bottom contact layer located above the silicon-on-insulator structure, wherein the first bottom contact layer is comprised of indium gallium phosphide;
second bottom contact layer located on the first bottom contact layer, wherein the second bottom contact layer is comprised of zinc gallium-arsenide;
a back surface and absorption layer located on the second bottom contact layer, wherein the back surface and absorption layer is comprised of zinc aluminum-gallium-arsenide;
a first absorption layer located on the back surface and absorption layer, wherein the first absorption layer is comprised of zinc aluminum-gallium-arsenide;
a second absorption layer located on the first absorption layer, wherein the second absorption layer is comprised of not intentionally doped (NID) aluminum-gallium-arsenide;
a third absorption layer located on the second absorption layer, wherein the third absorption layer is comprised of silicon aluminum-gallium-arsenide;
a window and absorption layer located on the third absorption layer, wherein the window and absorption layer is comprised of silicon aluminum-gallium-arsenide; and
a top contact layer located on the window and absorption layer, wherein the top contact layer is comprised of silicon gallium-arsenide.

18. The semiconductor structure of claim 17, further comprising:
a passivation film formed on the surfaces of the semiconductor structure.

19. The semiconductor structure of claim 17, further comprising:
electrodes on the uncovered surfaces of the semiconductor structure, wherein the electrodes extend above and beyond the passivation layer.
